(19) United States
(12) Patent Application Publication
(10) Pub. No.: US 2010/0215919 A1
(43) Pub. Date: Aug. 26, 2010

(54) ON-PRESS DEVELOPABLE IMAGEABLE ELEMENTS

(76) Inventors: Ting Tao, Fort Collins, CO (US); Eric E. Clark, Loveland, CO (US)

Correspondence Address: Amelia Buharin, Patent Legal Staff,;Eastman Kodak Company, 343 State Street, Rochester, NY, 14650-2201, US

(21) Appl. No.: 12/389,419

(22) Filed: Feb. 20, 2009

(51) Int. Cl. B32B 3/10; G03F 7/09; G03F 7/38; G03F 7/32

(52) U.S. Cl. 428/195.1; 430/286.1; 430/278.1; 430/302

(57) ABSTRACT

Negative-working, on-press developable imageable element have improved shelf life and press run length because they include a free radically polymerizable composition comprising two or more ethylenically unsaturated compounds, each of which has two or more terminal acrylate groups, provided at least one of the ethylenically unsaturated compounds further comprises alkylene glycol units. In addition, the molar ratio of terminal acrylate groups to the alkylene glycol units in the non-polymeric free radically polymerizable composition is from about 1.25:1 to about 3:1.

### FIELD OF THE INVENTION

This invention relates to negative-working imageable elements such as negative-working lithographic printing plate precursors containing specific free radically polymerizable compounds in the imageable layer. These imageable elements can be developed on-press after imaging. The invention also relates to a method of using these imageable elements to form imaged elements such as lithographic printing plates.

### BACKGROUND OF THE INVENTION

Radiation-sensitive compositions are routinely used in the preparation of imageable materials including lithographic printing plate precursors. Such compositions generally include a radiation-sensitive component, an initiator system, and a binder, each of which has been the focus of research to provide various improvements in physical properties, imaging performance, and image characteristics.

Recent developments in the field of printing plate precursors concern the use of radiation-sensitive compositions that can be imaged by means of lasers or laser diodes, and more particularly, that can be imaged and/or developed on-press. Laser exposure does not require conventional silver halide graphic arts films as intermediate information carriers (or “masks”) since the lasers can be controlled directly by computers. High-performance lasers or laser-diodes that are used in commercially-available image-setters generally emit radiation having a wavelength of at least 700 nm, and thus the radiation-sensitive compositions are required to be sensitive in the near-infrared or infrared region of the electromagnetic spectrum. However, other useful radiation-sensitive compositions are designed for imaging with ultraviolet or visible radiation.

There are two possible ways of using radiation-sensitive compositions for the preparation of printing plates. For negative-working printing plates, exposed regions in the radiation-sensitive compositions are hardened and unexposed regions are washed off during development. For positive-working printing plates, the exposed regions are dissolved in a developer and the unexposed regions become an image.

Various negative-working radiation compositions and imageable elements containing polymer binders are known in the art. Some of these compositions and elements are described for example in U.S. Pat. No. 6,569,603 (Furukawa), U.S. Pat. No. 6,309,792 (Hauck et al.), U.S. Pat. No. 6,582,882 (Pappas et al.), U.S. Pat. No. 6,787,281 (Tao et al.), U.S. Pat. No. 6,893,797 (Munnelly et al.), U.S. Pat. No. 7,175,969 (Ray et al.), U.S. Pat. No. 7,172,850 (Munnelly et al.), U.S. Pat. No. 7,332,253 (Tao et al.), U.S. Pat. No. 7,326,521 (Tao et al.), U.S. Patent Application Publications 2003/0118939 (West et al.), 2005/0003285 (Hayashi et al.), 2005/0008971 (Mitsumoto et al.), 2005/0204943 (Makino et al.), and 2007/0184380 (Tao et al.), and EP Publications 1,079,276A1 (Lifka et al.), EP 1,182,033A (Fujimaki et al.), and EP 1,449,650A1 (Goto).

Various negative-working imageable elements have been designed for processing or development “on-press” using a fountain solution, lithographic printing ink, or both. For example, such elements are described in U.S. Patent Application Publication 2005-263021 (Mitsumoto et al.) and in U.S. Pat. No. 6,071,675 (Teng), U.S. Pat. No. 6,387,595 (Teng), U.S. Pat. No. 6,482,571 (Teng), U.S. Pat. No. 6,495,310 (Teng), U.S. Pat. No. 6,541,183 (Teng), U.S. Pat. No. 6,548,222 (Teng), U.S. Pat. No. 6,576,401 (Teng), U.S. Pat. No. 6,899,994 (Huang et al.), U.S. Pat. No. 6,902,866 (Teng), and U.S. Pat. No. 7,089,856 (Teng).

Various free radically polymerizable compounds are used in the negative-working imageable elements of the art. Such compounds may include terminal acrylate groups that can be polymerized in the presence of free radicals. Some polymerizable compositions are sensitive in the UV and visible regions of the electromagnetic spectrum for flexographic printing plates as described in U.S. Pat. No. 6,127,094 (Victor et al.).

### SUMMARY OF THE INVENTION

The present invention provides a negative-working, on-press developable imageable element comprising a substrate having thereon an imageable layer as the outermost layer, the imageable layer comprising:

a non-polymeric free radically polymerizable composition,

an initiator composition capable of generating radicals sufficient to initiate polymerization of the free radically polymerizable composition upon exposure to imaging infrared radiation,

an infrared radiation absorbing compound, and

one or more non-free radically reactive polymeric binders,

wherein the free radically polymerizable composition comprises two or more ethylenically unsaturated compounds, each of which has two or more terminal acrylate groups, provided at least one of the ethylenically unsaturated compounds further comprises alkylene glycol units, and

further provided that the molar ratio of terminal acrylate groups to the alkylene glycol units in the non-polymeric free radically polymerizable composition is from about 1.25:1 to about 3:1.

The invention also provides a method of making an imaged element comprising:

A) imagewise exposing the negative-working imageable element of this invention to form exposed and non-exposed regions,

B) with or without a preheat step, developing the imagewise exposed element on-press using a fountain solution, lithographic printing ink, or both, to remove predominantly only the non-exposed regions.

An imaged lithographic printing plate can be obtained from the method of this invention, and such lithographic printing plate can have a sulfuric acid anodized aluminum-containing substrate.

The imageable elements of this invention are advantageously designed for on-press development as described in more detail below. In addition, we discovered that some IR-sensitive, on-press developable imageable elements suffer from short press run length and post-development coating retention in non-imaged areas after an accelerated aging in the presence of high humidity, especially when sulfuric acid-anodized aluminum substrates are used. The present invention solves these problems and provides improved shelf-life. In addition, the imageable elements of this invention exhibit desirable image speed and improved press run length.

These advantages are achieved by using specific free radically polymerizable compounds with prescribed amounts of terminal acrylate groups and alkylene oxide units as defined herein.

### DETAILED DESCRIPTION OF THE INVENTION

### Definitions

Unless the context indicates otherwise, when used herein, the terms “imageable element”, “lithographic printing plate precursor”, and “printing plate precursor” are meant to be references to embodiments of the present invention.

In addition, unless the context indicates otherwise, the various components described herein such as “primary polymeric binder”, “secondary polymeric binder”, “free radically ethylenically polymerizable compound”, “infrared radiation absorbing compound”, and similar terms also refer to mixtures of such components. Thus, the use of the articles “a”, “an”, and “the” is not necessarily meant to refer to only a single component.

Moreover, unless otherwise indicated, percentages refer to percents by dry weight.

For clarification of definitions for any terms relating to polymers, reference should be made to “Glossary of Basic Terms in Polymer Science” as published by the International Union of Pure and Applied Chemistry (“IUPAC”), Pure Appl. Chem. 68, 2287-2311 (1996). However, any definitions explicitly set forth herein should be regarded as controlling.

“Graft” polymer or copolymer refers to a polymer having a side chain that has a molecular weight of at least 200.

The term “polymer” refers to high and low molecular weight polymers including oligomers and includes homopolymers and copolymers.

The term “copolymer” refers to polymers that are derived from two or more different monomers.

The term “backbone” refers to the chain of atoms (carbon or heteroatoms) in a polymer to which a plurality of pendant groups are attached. One example of such a backbone is an “all carbon” backbone obtained from the polymerization of one or more ethylenically unsaturated polymerizable monomers. However, other backbones can include heteroatoms wherein the polymer is formed by a condensation reaction or some other means.

The terms “terminal acrylate group” and “alkylene glycol unit” are defined in more detail below.

### Imageable Layers

The imageable elements include an infrared (IR) radiation-sensitive composition disposed on a suitable substrate to form an imageable layer. The imageable elements may have any utility wherever there is a need for an applied coating that is polymerizable using suitable infrared radiation, and particularly where it is desired to remove non-exposed regions of the coating instead of exposed regions. The IR radiation-sensitive compositions can be used to prepare an imageable layer in imageable elements such as printed forms for example lithographic printing plate precursors that are defined in more detail below.

These IR radiation-sensitive compositions include a non-polymeric free radically polymerizable composition that comprises two or more ethylenically unsaturated compounds, each of which has two or more terminal acrylate groups. At least one of the ethylenically unsaturated compounds further comprises alkylene glycol units.

In some embodiments, at least one ethylenically unsaturated compound has at least two or more terminal acrylate groups as well as alkylene glycol units. In still other embodiments, at least one of the ethylenically unsaturated compounds has two or more terminal acrylate groups but does not contain alkylene glycol units.

Each of the ethylenically unsaturated compounds independently has a molecular weight of less than 5,000 and typically from about 120 to about 2,500.

By “terminal acrylate group”, we mean a group having the following structure:

H₂C═C(R₁)—C(═O)—

wherein R₁ is defined below.

By “alkylene glycol unit”, we mean a group having the following structure:

—[—CH(R′)—CH(R″)—O—]ₙ—

wherein R′, R″, and n are defined below.

In most embodiments, the ethylenically unsaturated compounds containing the alkylene glycol units are represented by the following Structure (Ia):

H₂C═C(R₁)—C(═O)—X—[—CH(R′)—CH(R″)—O—]ₙ— (Ia)

wherein R₁ is hydrogen or methyl, R′ and R″ are independently hydrogen or an alkyl group having 1 to 4 carbon atoms (such as methyl, ethyl, isopropyl, n-butyl or t-butyl), X is oxy, —NH—, thio, seleno, or an aliphatic chain having 1 to 6 atoms in the chain, and n is an integer of from 1 to 50. The aliphatic chain can include terminal carbon, nitrogen, oxygen, or sulfur atoms, or such heteroatoms throughout the chain, the aliphatic chain can be substituted or unsubstituted with various groups. In most instances, the aliphatic chain is a substituted or unsubstituted alkylene group having 1 to 6 carbon atoms. In some embodiments, R′ and R″ are independently hydrogen, methyl, or ethyl, or typically they are independently hydrogen or methyl.

In some embodiments, X is oxy or —NH—, or n is from 1 to 10, or both conditions apply.

The molar ratio of terminal acrylate groups to the alkylene glycol units in the non-polymeric free radically polymerizable composition is from about 1:25 to about 3: 1, or typically from about 1.25:1 to about 2.5:1.

The ethylenically unsaturated compounds used in this invention can be purchased from a variety of commercial sources including Aldrich Chemical Company, Kowa American, and Scientific Polymer Products, Inc.

Representative ethylenically unsaturated compounds that may or may not include alkylene glycol units include but are not limited to, diacrylate esters of alkanolglycidyl ethers such as 1,4,butanedioldiglycidyl ether, ethoxylated trimethylolpropanetriacrylate, ethoxylated trimethylolpropanetrimethacrylate, polyoxy ethylene glycol diacrylate, polyoxy ethylene glycol dimethacrylate, ethylene glycol di(meth)acrylate, propylene glycol di(meth)acrylate, diethylene glycol di(meth)acrylate, dipropylene glycol di(meth)acrylate, triethylene glycol di(meth)acrylate, tetraethylene glycol di(meth)acrylate, polyethylene glycol di(meth)acrylate, polypropylene glycol di(meth)acrylate, 1,4-butanediol diacrylate, 1,6-hexanediol dimethacrylate, 1,12-dodecanediol dimethacrylate, ethoxylated bisphenol A di(meth)acrylate, bisphenol A diglycidyl ether di(meth)acrylate, resorcinol diglycidyl ether di(meth)acrylate, ethoxylated glycerol tri(meth)acrylate, propylated glycerol tri(meth)acrylate, alkoxylated hexanediol diacrylate, alkoxylated cyclohexene dimethanol diacrylate, propoxylated neopentyl glycol diacrylate, pentaerythritol(meth)triacrylate, pentaerythritol tetra(meth)acrylate, ethoxylated pentaerthritol tetra(meth)acrylate, ethoxylated(20)trimethylolpropane tri(meth)acrylate, dipentaerythritol penta(meth)acrylate, dipentaerythritol hexa(meth)acrylate, and tris(2-hydroxyethyl)isocyanurate triacrylate.

The IR radiation-sensitive composition can also include other non-polymeric free radical polymerizable compounds that are not defined above. For example, such free radically polymerizable compounds can contain one or more free radical polymerizable monomers/oligomers having one or more crosslinkable/polymerizable ethylenically unsaturated groups. Suitable ethylenically unsaturated components that can be polymerized or crosslinked include ethylenically unsaturated polymerizable monomers/oligomers that have or more polymerizable groups, including unsaturated esters of alcohols, such as acrylate and methacrylate esters of polyols. Oligomers or prepolymers, such as urethane acrylates and methacrylates and epoxide acrylates and methacrylates can also be used. In some embodiments, the free radically polymerizable component comprises carboxy groups.

Numerous other free radically polymerizable components are known to those skilled in the art and are described in considerable literature including Photoreactive Polymers: The Science and Technology of Resists, A Reiser, Wiley, New York, 1989, pp. 102-177, by B. M. Monroe in Radiation Curing: Science and Technology, S. P. Pappas, Ed., Plenum, New York, 1992, pp. 399-440, and in “Polymer Imaging” by A. B. Cohen and P. Walker, in Imaging Processes and Material, J. M. Sturge et al. (Eds.), Van Nostrand Reinhold, New York, 1989, pp. 226-262. For example, useful free radically polymerizable components are also described in EP 1,182,033A1 (noted above), beginning with paragraph [0170], and in U.S. Pat. No. 6,309,792 (Hauck et al.), U.S. Pat. No. 6,569,603 (Furukawa), and U.S. Pat. No. 6,893,797 (Munnelly et al.).

Particularly useful ethylenically unsaturated compounds that do not include alkylene glycol units include but are not limited to, urea urethane(meth)acrylates or urethane(meth)acrylates having multiple polymerizable groups. For example, a free radically polymerizable component can be prepared by reacting DESMODUR® N100 aliphatic polyisocyanate resin based on hexamethylene diisocyanate (Bayer Corp., Milford, Conn.) with hydroxyethyl acrylate and pentaerythritol triacrylate. Useful free radically polymerizable compounds include NK Ester A-DPH (dipentaerythritol hexaacrylate) that is available from Kowa American, and Sartomer 399 (dipentaerythritol pentaacrylate), and Sartomer 355 (di-trimethylolpropane tetraacrylate), Sartomer 295 (pentaerythritol tetraacrylate) that are available from Sartomer Company, Inc.

Particularly useful ethylenically unsaturated compounds that contain both terminal acrylate groups and alkylene glycol units include but are not limited to, Sartomer 415 [ethoxylated(20)trimethylolpropane triacrylate], Sartomer 494 (ethoxylated(4) pentaerythritol tetraacrylate), Sartomer 499 (ethoxylated(6)trimethylolpropane triacrylate), and Sartomer 349 (ethoxylated(3)bisphenol A diacrylate) that are also available from Sartomer Company, Inc.

The amount of the free radically polymerizable composition (total ethylenically unsaturated compounds) in the imageable layer is at least 10 weight % and up to 80 weight %, with the typical amount being from about 25 to about 65 weight %.

The IR radiation-sensitive composition also includes an initiator composition that includes one or more initiators that are capable of generating free radicals sufficient to initiate polymerization of all the various free radically polymerizable compounds upon exposure of the composition to imaging radiation. The initiator composition is generally responsive to infrared imaging radiation corresponding to the spectral range of at least 700 nm and up to and including 1400 nm (typically from about 750 to about 1250 nm). Initiator compositions are used that are appropriate for the desired imaging wavelength(s).

Such compositions can include a variety of initiator compounds including but not limited to onium salts, amines, anilinodiacetic acids or derivatives thereof, N-phenyl glycine and derivatives thereof, N,N-dialkylaminobenzoic acid esters, organic boron salts, s-triazines, benzoyl-substituted compounds, trihaloalkyl-substituted compounds, metallocenes (such as titanocenes and ferrocenes), ketoximes, oxime ethers and esters, alkyltriarylborates, benzoin ethers and esters, thio compounds, organic peroxides, or combinations thereof. Other known initiator compositions are described for example in U.S. Patent Application Publication 2003/0064318 (Huang et al.).

The initiator compound(s) could be present in the imageable layer in an amount of at least 1 and up to 25 weight %.

Of the onium salts, useful compounds include iodonium, phosphonium, sulfonium, oxysulfoxonium, oxysulfonium, arsonium, selenoium, halonium, and diazonium salts.

Useful iodonium cations are well known in the art including but not limited to, U.S. Patent Application Publication 2002/0068241 (Oohashi et al.), WO 2004/101280 (Munnelly et al.), and U.S. Pat. No. 5,086,086 (Brown-Wensley et al.), U.S. Pat. No. 5,965,319 (Kobayashi), and U.S. Pat. No. 6,051,366 (Baumann et al.). For example, a useful iodonium cation includes a positively charged iodonium, (4-methylphenyl)[4-(2-methylpropyl)phenyl]- moiety and a suitable negatively charged counterion. A representative example of such an iodonium salt is available as Irgacure® 250 from Ciba Specialty Chemicals (Tarrytown, N.Y.) that is (4-methylphenyl)[4-(2-methylpropyl)phenyl]iodonium hexafluorophosphate and is supplied in a 75% propylene carbonate solution.

The iodonium cations can be paired with a suitable number of negatively-charged counterions such as halides, hexafluorophosphate, thiosulfate, hexafluoroantimonate, tetrafluoroborate, sulfonates, hydroxide, perchlorate, and others readily apparent to one skilled in the art.

Thus, the iodonium cations can be supplied as part of one or more iodonium salts, and as described below, the iodonium cations can be supplied as iodonium borates also containing suitable boron-containing anions. For example, the iodonium cations and the boron-containing anions can be supplied as part of salts that are combinations of Structures (IB) and (IBz) described in U.S. Patent Application Publication 2007/0275322 (Tao et al.) or both the iodonium cations and boron-containing anions can be supplied from different sources. However, if they are supplied at least from the iodonium borate salts, since such salts generally supply about a 1:1 molar ratio of iodonium cations to boron-containing anions, additional iodonium cations may be supplied from other sources, for example, from iodonium salts described above.

For example, the imageable layer (and element) can comprise a mixture of iodonium cations, some of which are derived from an iodonium borate (described below) and others of which are derived from a non-boron-containing iodonium salt (described above). When both types of iodonium salts are present, the molar ratio of iodonium derived from the iodonium borate to the iodonium derived from the non-boron-containing iodonium salt can be up to 5:1.

One class of useful iodonium cations include diaryliodonium cations that are represented by the following Structure (IB):

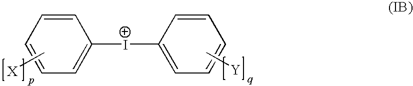

wherein X and Y are independently halo groups (for example, fluoro, chloro, or bromo), substituted or unsubstituted alkyl groups having 1 to 20 carbon atoms (for example, methyl, chloromethyl, ethyl, 2-methoxyethyl, n-propyl, isopropyl, isobutyl, n-butyl, t-butyl, all branched and linear pentyl groups, 1-ethylpentyl, 4-methylpentyl, all hexyl isomers, all octyl isomers, benzyl, 4-methoxybenzyl, p-methylbenzyl, all dodecyl isomers, all icosyl isomers, and substituted or unsubstituted mono-and poly-, branched and linear haloalkyls), substituted or unsubstituted alkyloxy having 1 to 20 carbon atoms (for example, substituted or unsubstituted methoxy, ethoxy, isopropoxy, t-butoxy, (2-hydroxytetradecyl)oxy, and various other linear and branched alkyleneoxyalkoxy groups), substituted or unsubstituted aryl groups having 6 or 10 carbon atoms in the carbocyclic aromatic ring (such as substituted or unsubstituted phenyl and naphthyl groups including mono- and polyhalophenyl and naphthyl groups), or substituted or unsubstituted cycloalkyl groups having 3 to 8 carbon atoms in the ring structure (for example, substituted or unsubstituted cyclopropyl, cyclopentyl, cyclohexyl, 4-methylcyclohexyl, and cyclooctyl groups). Typically, X and Y are independently substituted or unsubstituted alkyl groups having 1 to 8 carbon atoms, alkyloxy groups having 1 to 8 carbon atoms, or cycloalkyl groups having 5 or 6 carbon atoms in the ring, and more preferably, X and Y are independently substituted or unsubstituted alkyl groups having 3 to 6 carbon atoms (and particularly branched alkyl groups having 3 to 6 carbon atoms). Thus, X and Y can be the same or different groups, the various X groups can be the same or different groups, and the various Y groups can be the same or different groups. Both “symmetric” and “asymmetric” diaryliodonium borate compounds are contemplated but the “symmetric” compounds are preferred (that is, they have the same groups on both phenyl rings).

In addition, two or more adjacent X or Y groups can be combined to form a fused carbocyclic or heterocyclic ring with the respective phenyl groups.

The X and Y groups can be in any position on the phenyl rings but typically they are at the 2- or 4-positions on either or both phenyl rings.

Despite what type of X and Y groups are present in the iodonium cation, the sum of the carbon atoms in the X and Y substituents generally is at least 6, and typically at least 8, and up to 40 carbon atoms. Thus, in some compounds, one or more X groups can comprise at least 6 carbon atoms, and Y does not exist (q is 0). Alternatively, one or more Y groups can comprise at least 6 carbon atoms, and X does not exist (p is 0). Moreover, one or more X groups can comprise less than 6 carbon atoms and one or more Y groups can comprise less than 6 carbon atoms as long as the sum of the carbon atoms in both X and Y is at least 6. Still again, there may be a total of at least 6 carbon atoms on both phenyl rings.

In Structure IB, p and q are independently 0 or integers of 1 to 5. Typically, both p and q are at least 1, or each of p and q is 1. Thus, it is understood that the carbon atoms in the phenyl rings that are not substituted by X or Y groups have a hydrogen atom at those ring positions.

Useful boron-containing anions are organic anions having four organic groups attached to the boron atom. Such organic anions can be aliphatic, aromatic, heterocyclic, or a combination of any of these. Generally, the organic groups are substituted or unsubstituted aliphatic or carbocyclic aromatic groups. For example, useful boron-containing anions can be represented by the following Structure (IBz):

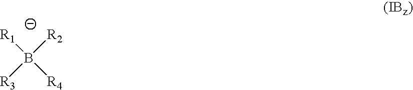

wherein R₁, R₂, R₃, and R₄ are independently substituted or unsubstituted alkyl groups having 1 to 12 carbon atoms (such as methyl, ethyl, n-propyl, isopropyl, n-butyl, isobutyl, t-butyl, all pentyl isomers, 2-methylpentyl, all hexyl isomers, 2-ethylhexyl, all octyl isomers, 2,4,4-trimethylpentyl, all nonyl isomers, all decyl isomers, all undecyl isomers, all dodecyl isomers, methoxymethyl, and benzyl) other than fluoroalkyl groups, substituted or unsubstituted carbocyclic aryl groups having 6 to 10 carbon atoms in the aromatic ring (such as phenyl, p-methylphenyl, 2,4-methoxyphenyl, naphthyl, and pentafluorophenyl groups), substituted or unsubstituted alkenyl groups having 2 to 12 carbon atoms (such as ethenyl, 2-methylethenyl, allyl, vinylbenzyl, acryloyl, and crotonotyl groups), substituted or unsubstituted alkynyl groups having 2 to 12 carbon atoms (such as ethynyl, 2-methylethynyl, and 2,3-propynyl groups), substituted or unsubstituted cycloalkyl groups having 3 to 8 carbon atoms in the ring structure (such as cyclopropyl, cyclopentyl, cyclohexyl, 4-methylcyclohexyl, and cyclooctyl groups), or substituted or unsubstituted heterocyclyl groups having 5 to 10 carbon, oxygen, sulfur, and nitrogen atoms (including both aromatic and non-aromatic groups, such as substituted or unsubstituted pyridyl, pyrimidyl, furanyl, pyrrolyl, imidazolyl, triazolyl, tetrazoylyl, indolyl, quinolinyl, oxadiazolyl, and benzoxazolyl groups). Alternatively, two or more of R₁, R₂, R₃, and R₄ can be joined together to form a heterocyclic ring with the boron atom, such rings having up to 7 carbon, nitrogen, oxygen, or nitrogen atoms. None of the R₁ through R₄ groups contains halogen atoms and particularly fluorine atoms.

Typically, R₁, R₂, R₃, and R₄ are independently substituted or unsubstituted alkyl or aryl groups as defined above, and more typically, at least 3 of R₁, R₂, R₃, and R₄ are the same or different substituted or unsubstituted aryl groups (such as substituted or unsubstituted phenyl groups). For example, all of R₁, R₂, R₃, and R₄ can be the same or different substituted or unsubstituted aryl groups, or all of the groups are the same substituted or unsubstituted phenyl group. Z⁻ can be a tetraphenyl borate wherein the phenyl groups are substituted or unsubstituted (for example, all are unsubstituted phenyl groups).

Some representative iodonium borate compounds include but are not limited to, 4-octyloxyphenyl phenyliodonium tetraphenylborate, [4-[(2-hydroxytetradecyl)-oxy]phenyl]phenyliodonium tetraphenylborate, bis(4-t-butylphenyl)iodonium tetraphenylborate, 4-methylphenyl-4′-hexylphenyliodonium tetraphenylborate, 4-methylphenyl-4′-cyclohexylphenyliodonium tetraphenylborate, bis(t-butylphenyl)iodonium tetrakis(pentafluorophenyl)borate, 4-hexylphenyl-phenyliodonium tetraphenylborate, 4-methylphenyl-4′-cyclohexylphenyliodonium n-butyltriphenylborate, 4-cyclohexylphenyl-4′-phenyliodonium tetraphenylborate, 2-methyl-4-t-butylphenyl-4′-methylphenyliodonium tetraphenylborate, 4-methylphenyl-4′-pentylphenyliodonium tetrakis[3,5-bis(trifluoromethyl)phenyl]-borate, 4-methoxyphenyl-4′-cyclohexylphenyliodonium tetrakis(pentafluorophenyl)borate, 4-methylphenyl-4′-dodecylphenyliodonium tetrakis(4-fluorophenyl)borate, bis(dodecylphenyl)iodonium tetrakis(pentafluorophenyl)-borate, and bis(4-t-butylphenyl)iodonium tetrakis(1-imidazolyl)borate. Mixtures of two or more of these compounds can also be used in the iodonium borate initiator composition.

The iodonium cations and boron-containing anions are generally present in the imageable layer in a combined amount of at least 1% and up to and including 15%, and typically at least 4 and up to and including about 10%, based on total dry weight of the imageable layer. The optimum amount of the various initiator components may differ for various compounds and the sensitivity of the radiation-sensitive composition that is desired and would be readily apparent to one skilled in the art.

The imageable layer may also include heterocyclic mercapto compounds including mercaptotriazoles, mercaptobenzimidazoles, mercaptobenzoxazoles, mercaptobenzothiazoles, mercaptobenzoxadiazoles, mercaptotetrazoles, such as those described for example in U.S. Pat. No. 6,884,568 (Timpe et al.) in amounts of at least 0.5 and up to and including 10 weight % based on the total solids of the radiation-sensitive composition. Useful mercaptotriazoles include 3-mercapto-1,2,4-triazole, 4-methyl-3-mercapto-1,2,4-triazole, 5-mercapto-1-phenyl-1,2,4-triazole, 4-amino-3-mercapto-1,2,4,-triazole, 3-mercapto-1,5-diphenyl-1,2,4-triazole, and 5-(p-aminophenyl)-3-mercapto-1,2,4-triazole.

The IR radiation-sensitive composition sensitivity is provided by the presence of one or more infrared radiation absorbing compounds, chromophores, or sensitizers that absorb imaging radiation, or sensitize the composition to imaging infrared radiation having a λₘₐₓ of from about 700 nm and up to and including 1400 nm, and typically from about 700 to about 1200 nm.

Useful IR radiation absorbing chromophores include various IR-sensitive dyes (“IR dyes”). Examples of suitable IR dyes comprising the desired chromophore include but are not limited to, azo dyes, squarilium dyes, croconate dyes, triarylamine dyes, thioazolium dyes, indolium dyes, oxonol dyes, oxaxolium dyes, cyanine dyes, merocyanine dyes, phthalocyanine dyes, indocyanine dyes, indotricarbocyanine dyes, oxatricarbocyanine dyes, thiocyanine dyes, thiatricarbocyanine dyes, cryptocyanine dyes, naphthalocyanine dyes, polyaniline dyes, polypyrrole dyes, polythiophene dyes, chalcogenopyryloarylidene and bi(chalcogenopyrylo) polymethine dyes, oxyindolizine dyes, pyrylium dyes, pyrazoline azo dyes, oxazine dyes, naphthoquinone dyes, anthraquinone dyes, quinoneimine dyes, methine dyes, arylmethine dyes, squarine dyes, oxazole dyes, croconine dyes, porphyrin dyes, and any substituted or ionic form of the preceding dye classes. Suitable dyes are also described in U.S. Pat. No. 5,208,135 (Patel et al.), U.S. Pat. No. 6,153,356 (Urano et al.), U.S. Pat. No. 6,264,920 (Achilefu et al.), U.S. Pat. No. 6,309,792 (Hauck et al.), U.S. Pat. No. 6,569,603 (noted above), U.S. Pat. No. 6,787,281 (Tao et al.), U.S. Pat. No. 7,135,271 (Kawaushi et al.), and EP 1,182,033A2 (noted above). Infrared radiation absorbing N-alkylsulfate cyanine dyes are described for example in U.S. Pat. No. 7,018,775 (Tao). A general description of one class of suitable cyanine dyes is shown by the formula in paragraph [0026] of WO 2004/101280 (Munnelly et al.).

In addition to low molecular weight IR-absorbing dyes, IR dye chromophores bonded to polymers can be used as well. Moreover, IR dye cations can be used as well, that is, the cation is the IR absorbing portion of the dye salt that ionically interacts with a polymer comprising carboxy, sulfo, phospho, or phosphono groups in the side chains.

Near infrared absorbing cyanine dyes are also useful and are described for example in U.S. Pat. No. 6,309,792 (noted above), U.S. Pat. No. 6,264,920 (Achilefu et al.), U.S. Pat. No. 6,153,356 (noted above), and U.S. Pat. No. 5,496,903 (Watanabe et al.). Suitable dyes may be formed using conventional methods and starting materials or obtained from various commercial sources including American Dye Source (Baie D'Urfe, Quebec, Canada) and FEW Chemicals (Germany). Other useful dyes for near infrared diode laser beams are described in U.S. Pat. No. 4,973,572 (DeBoer).

Some useful infrared radiation absorbing dyes have a tetraaryl pentadiene chromophore. Such chromophore generally includes a pentadiene linking group having 5 carbon atoms in the chain, to which are attached two substituted or unsubstituted aryl groups at each end of the linking group. The pentadiene linking group can also be substituted with one or more substituents in place of the hydrogen atoms, or two or more hydrogen atoms can be replaced with atoms to form a ring in the linking group as long as there are alternative carbon-carbon single bonds and carbon-carbon double bonds in the chain.

Such IR-sensitive dyes can be represented by the following Structure DYE-I:

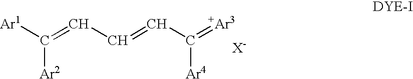

wherein Ar¹ through Ar⁴ are the same or different substituted or unsubstituted aryl groups having at least carbon atoms in the aromatic ring (such as phenyl, naphthyl, and anthryl, or other aromatic fused ring systems) wherein 1 to 3 of the aryl groups are substituted with the same or different tertiary amino group (such as in the 4-position of a phenyl group). Typically two of the aryl groups are substituted with the same or different tertiary amino group, and usually at different ends of the polymethine chain (that is, molecule). For example, Ar¹ or Ar² and Ar³ or Ar⁴ bear the tertiary amine groups. Representative amino groups include but are not limited to those substituted with substituted or unsubstituted alkyl groups having up to 10 carbon atoms or aryl groups such as dialkylamino groups (such as dimethylamino and diethylamino), diarylamino groups (such as diphenylamino), alkylarylamino groups (such as N-methylanilino), and heterocyclic groups such as pyrrolidino, morpholino, and piperidino groups. The tertiary amino group can form part of a fused ring such that one or more of Ar¹ through Ar⁴ can represent a julolidine group.

Besides the noted tertiary groups noted above, the aryl groups can be substituted with one or more substituted or unsubstituted alkyl groups having 1 to 10 carbon atoms, halo atoms (such as chloro or bromo), hydroxyl groups, thioether groups, and substituted or unsubstituted alkoxy groups having 1 to 10 carbon atoms. Substituents that contribute electron density to the conjugated system are useful. While they are not specifically shown in Structure (DYE-I), substituents or fused rings may also exist on (or as part of) the conjugated chain connecting the aryl groups.

In Structure (DYE-I), X⁻ is a suitable counterion that may be derived from a strong acid, and include such anions as ClO₄⁻, BF₄⁻, CF₃SO₃⁻, PF₆⁻, AsF₆⁻, SbF₆⁻, and perfluoroethylcyclohexylsulfonate. Other cations include boron-containing anions as described above (borates), methylbenzenesulfonic acid, benzenesulfonic acid, methanesulfonic acid, p-hydroxybenzenesulfonic acid, p-chlorobenzenesulfonic acid, and halides.

Useful infrared radiation absorbing dyes can be obtained from a number of commercial sources including Showa Denko (Japan) or they can be prepared using known starting materials and procedures.

Still other useful infrared radiation absorbing compounds are copolymers can comprise covalently attached ammonium, sulfonium, phosphonium, or iodonium cations and infrared radiation absorbing cyanine anions that have two or four sulfonate or sulfate groups, or infrared radiation absorbing oxonol anions, as described for example in U.S. Pat. No. 7,049,046 (Tao et al.).

The infrared radiation absorbing compounds can be present in the IR-radiation sensitive composition (or imageable layer) in an amount generally of at least 1% and up to and including 30% and typically at least 3 and up to and including 20%, based on total solids in the composition, that also corresponds to the total dry weight of the imageable layer. The particular amount needed for this purpose would be readily apparent to one skilled in the art.

The polymeric binders used in the imageable layer are non-free radical reactive polymeric binders, meaning that the polymers are not crosslinkable or polymerizable. In some embodiments, at least one of said non-free radical reactive polymeric binders is present as discrete particles.

For example, a primary non-free radically reactive polymeric binder may be optionally present a discrete particles, and a secondary non-free radically reactive polymeric binder may be present that comprises a poly(vinyl acetate) that has a degree of hydrolysis of less than 60 mol % and not present as discrete particles.

In some embodiments, the primary non-free radically polymerizable polymeric binder is present in an amount of at least 5 and up to 70 weight %, and the secondary non-free radically polymerizable polymeric binder is present in an amount of at least 1 and up to 40 weight %, both based on total dry imageable layer weight. The weight ratio of the secondary non-free radically polymerizable polymeric binder to the first non-free radically polymerizable polymeric binder can be from about 1:1 to about 1:20 (typically from about 1:1 to about 1:15, or from about 1:1 to about 1:10). For example, the first polymeric binder is present in an amount of from about 10 to about 40 weight % (typically from about 15 to about 30 weight %), and the second polymeric binder is present in an amount of from about 0.5 to about 15 weight % (typically from about 1 to about 10 weight %), both based on the total dry weight of the imageable layer.

As noted above, at least one non-free radical reactive polymeric binder can be present as discrete particles having an average particle size of from about 10 to about 500 nm, and typically from about 150 to about 450 nm, and that are generally distributed uniformly within that layer. The particulate polymeric binders exist at room temperature as discrete particles, for example in an aqueous dispersion. However, the particles can also be partially coalesced or deformed, for example at temperatures used for drying coated imageable layer formulations. Even in this environment, the particulate structure is not destroyed. Such polymeric binders generally have a molecular weight (Mₙ) of at least 30,000 and typically at least 50,000 to about 100,000, or from about 60,000 to about 80,000, as determined by refractive index.

Useful particulate polymeric binders generally include polymeric emulsions or dispersions of polymers having hydrophobic backbones to which are attached pendant poly(alkylene oxide) side chains, cyano side chains, or both, that are described for example in U.S. Pat. No. 6,582,882 (Pappas et al.), U.S. Pat. No. 6,899,994 (Huang et al.), U.S. Pat. No. 7,005,234 (Hoshi et al.), and U.S. Pat. No. 7,368,215 (Munnelly et al.) and US Patent Application Publication 2005/0003285 (Hayashi et al.) that are all incorporated herein by reference. More specifically, such polymeric binders include but are not limited to, graft copolymers having both hydrophobic and hydrophilic segments, block and graft copolymers having polyethylene oxide (PEO) segments, polymers having both pendant poly(alkylene oxide) segments and cyano groups, and various hydrophilic polymeric binders that may have various hydrophilic groups such as hydroxyl, carboxy, hydroxyethyl, hydroxypropyl, amino, aminoethyl, aminopropyl, carboxymethyl, sulfono, or other groups readily apparent to a worker skilled in the art.

Alternatively, the particulate polymeric binders can also have a backbone comprising multiple (at least two) urethane moieties. Such polymeric binders generally have a molecular weight (Mₙ) of at least 2,000 and typically at least 100,000 to about 500,000, or from about 100,000 to about 300,000, as determined by dynamic light scattering.

Additional useful polymeric binders are particulate poly(urethane-acrylic) hybrids that are distributed (usually uniformly) throughout the imageable layer. Each of these hybrids has a molecular weight of from about 50,000 to about 500,000 and the particles have an average particle size of from about 10 to about 10,000 nm (typically from about 30 to about 500 nm or from about 30 to about 150 nm). These hybrids can be either “aromatic” or “aliphatic” in nature depending upon the specific reactants used in their manufacture. Blends of particles of two or more poly(urethane-acrylic) hybrids can also be used. Some poly(urethane-acrylic) hybrids are commercially available in dispersions from Air Products and Chemicals, Inc. (Allentown, Pa.), for example, as the Hybridur® 540, 560, 570, 580, 870, 878, 880 polymer dispersions of poly(urethane-acrylic) hybrid particles. These dispersions generally include at least 30% solids of the poly(urethane-acrylic) hybrid particles in a suitable aqueous medium that may also include commercial surfactants, anti-foaming agents, dispersing agents, anti-corrosive agents, and optionally pigments and water-miscible organic solvents.

The secondary polymeric binders described above may be homogenous, that is, non-particulate or dissolved in the coating solvent, or they may exist as discrete particles. Such secondary polymeric binders include but are not limited to, (meth)acrylic acid and acid ester resins [such as (meth)acrylates], polyvinyl acetals, phenolic resins, polymers derived from styrene, N-substituted cyclic imides or maleic anhydrides, such as those described in EP 1,182,033A1 (Fujimaki et al.) and U.S. Pat. No. 6,309,792 (Hauck et al.), U.S. Pat. No. 6,352,812 (Shimazu et al.), U.S. Pat. No. 6,569,603 (Furukawa et al.), and U.S. Pat. No. 6,893,797 (Munnelly et al.). Also useful are the vinyl carbazole polymers described in U.S. Pat. No. 7,175,949 (Tao et al.), and the polymers having pendant vinyl groups as described in U.S. Pat. No. 7,279,255 (Tao et al.), both incorporated herein by reference. Copolymers of polyethylene glycol methacrylate/acrylonitrile/styrene in particulate form, dissolved copolymers derived from carboxyphenyl methacrylamide/acrylonitrile/methacrylamide/N-phenyl maleimide, copolymers derived from polyethylene glycol methacrylate/acrylonitrile/vinyl carbazole/styrene/methacrylic acid, copolymers derived from N-phenyl maleimide/methacrylamide/methacrylic acid, copolymers derived from urethane-acrylic intermediate A (the reaction product ofp-toluene sulfonyl isocyanate and hydroxyl ethyl methacrylate)/acrylonitrile/N-phenyl maleimide, and copolymers derived from N-methoxymethyl methacrylamide/methacrylic acid/acrylonitrile/n-phenylmaleimide are useful.

In some embodiments of this invention the imageable element comprises a weight ratio of the secondary polymeric binder to the primary polymeric binder is from about 1:1 to about 1:20,

the primary polymeric binder being present in an amount of from about 15 to about 30 weight %, and the secondary polymeric binder being present in an amount of from about 1 to about 10 weight %, both based on the total dry weight of the imageable layer.

In still other embodiments, the imageable elements comprise a weight ratio of the secondary polymeric binder to the primary polymeric binder being from about 1:1 to about 1:20,

the primary polymeric binder is present in an amount of from about 10 to about 40 weight %, and the secondary polymeric binder being present in an amount of from about 0.5 to about 15 weight %, both based on the total dry weight of the imageable layer.

Moreover, in any of these embodiments, the imageable elements can comprise a weight ratio of the secondary polymeric binder to the primary polymeric binder is from about 1:1 to about 1:15,

the primary polymeric binder being present in an amount of from about 15 to about 30 weight %, and the secondary polymeric binder being present in an amount of from about 1 to about 10 weight %, both based on the total dry weight of the imageable layer.

The various primary and secondary polymeric binders can be obtained from a number of commercial sources, or prepared using known starting materials and reaction conditions.

The imageable layer can also include a spirolactone or spirolactam colorant precursor. Such compounds are generally colorless or weakly colored until the presence of an acid causes the ring to open providing a colored species, or more intensely colored species.

Examples of useful colorant precursors include but are not limited to, Crystal Violet Lactone, Malachite Green Lactone, 3-(N,N-diethylamino)-6-chloro-7-(β-ethoxyethylamino)fluoran, 3-(N,N,N-triethylamino)-6-methyl-7-anilinofluoran, 3-(N,N-diethylamino)-7-chloro-7-o-chlorofluoran, 2-(N-phenyl-N-methylamino)-6-(N-p-tolyl-N-ethyl)aminofluoran, 2-anilino-3-methyl-6-(N-ethyl-p-toluidino)fluoran, 3,6-dimethoxyfluoran, 3-(N,N-diethylamino)-5-methyl-7-(N,N-dibenzylamino)fluoran, 3-(N-cyclohexyl-N-methylamino)-6-methyl-7-anilinofluoran, 3-(N,N-diethylamino)-6-methyl-7-anilinofluoran, 3-(N,N-diethylamino)-6-methyl-7-xylidinofluoran, 3-(N,N-diethylamino)-6-methyl-7-chlorofluoran, 3-(N,N-diethylamino)-6-methoxy-7-chlorofluoran, 3-(N,N-diethylamino)-7-(4-chloroanilino)fluoran, 3-(N,N-diethylamio)-7-chlorofluoran, 3-(N,N-diethylamino)-7-benzylaminofluoran, 3-(N,N-diethylamino)-7,8-benzofluoran, 3-(N,N-dibutylamino)-6-methyl-7-anilinofluoran, 3-(N,N-dibutylamino)-6-methyl-7-xylidinofluoran, 3-piperidino-6-methyl-7-anilinofluoran, 3-pyrrolidino-6-methyl-7-anilinofluoran, 3,3-bis(1-ethyl-2-methylindol-3-yl)phthalide, 3,3-bis((1-n-butyl-2-methylindol-3-yl)phthalide, 3,3-bis(p-dimethylaminophenyl)-6-dimethylaminophthalide, 3-(4-diethylamino-2-ethoxyphenyl)-3-(1-ethyl-2-methylindol-3-yl)-4-azaphthalide, and 3-(4-diethylaminophenyl)-3-(1-ethyl-2-methylindol-3-yl)phthalide.

The colorant precursor described above can be present in an amount of at least 1 and up to 10 weight %, and typically from about 3 to about 6 weight %, based on the total dry imageable layer weight.

The radiation-sensitive composition (imageable layer) can further comprise one or more phosphate (meth)acrylates, each of which has a molecular weight generally greater than 200 and typically at least 300 and up to and including 1000. By “phosphate (meth)acrylate” we also mean to include “phosphate methacrylates” and other derivatives having substituents on the vinyl group in the acrylate moiety. Such compounds and their use in imageable layers are described in more detail in U.S. Pat. No. 7,175,969 (Ray et al.) that is incorporated herein by reference.

The phosphate (meth)acrylate can be present in the radiation-sensitive composition in an amount of at least 0.5 and up to and including 20% and typically at least 0.9 and up to and including 10%, based on total dry composition weight.

The imageable layer can also include a “primary additive” that is a poly(alkylene glycol) or an ether or ester thereof that has a molecular weight of at least 200 and up to and including 4000. This primary additive can be present in an amount of at least 2 and up to and including 50 weight %, based on the total dry weight of the imageable layer. Useful primary additives include, but are not limited to, one or more of polyethylene glycol, polypropylene glycol, polyethylene glycol methyl ether, polyethylene glycol dimethyl ether, polyethylene glycol monoethyl ether, polyethylene glycol diacrylate, ethoxylated bisphenol A di(meth)acrylate, and polyethylene glycol mono methacrylate.

The imageable layer can also include a “secondary additive” that is a poly(vinyl alcohol), a poly(vinyl pyrrolidone), poly(vinyl imidazole), or polyester in an amount of up to and including 20 weight % based on the total dry weight of the imageable layer.

Additional additives to the imageable layer include color developers or acidic compounds. As color developers, we mean to include monomeric phenolic compounds, organic acids or metal salts thereof, oxybenzoic acid esters, acid clays, and other compounds described for example in U.S. Patent Application Publication 2005/0170282 (Inno et al.). Specific examples of phenolic compounds include but are not limited to, 2,4-dihydroxybenzophenone, 4,4′-isopropylidene-diphenol (Bisphenol A), p-t-butylphenol, 2,4,-dinitrophenol, 3,4-dichlorophenol, 4,4′-methylene-bis(2,6′-di-t-butylphenol), p-phenylphenol, 1,1-bis(4-hydroxyphenyl)cyclohexane, 1,1-bis(4-hydroxyphenyl)-2-ethylhexene, 2,2-bis(4-hydroxyphenyl)butane, 2,2′-methylenebis(4-t-butylphenol), 2,2′-methylenebis(α-phenyl-p-cresol)thiodiphenol, 4,4′-thiobis(6-t-butyl-m-cresol)sulfonyldiphenol, p-butylphenol-formalin condensate, and p-phenylphenol-formalin condensate. Examples of useful organic acids or salts thereof include but are not limited to, phthalic acid, phthalic anhydride, maleic acid, benzoic acid, gallic acid, o-toluic acid, p-toluic acid, salicylic, 3-t-butylsalicylic, 3,5-di-3-t-butylsalicylic acid, 5-α-methylbenzylsalicylic acid, 3,5-bis(α-methylbenzyl)salicylic acid, 3-t-octylsalicylic acid, and their zinc, lead, aluminum, magnesium, and nickel salts. Examples of the oxybenzoic acid esters include but are not limited to, ethyl p-oxybenzoate, butyl p-oxybenzoate, heptyl p-oxybenzoate, and benzyl p-oxybenzoate. Such color developers may be present in an amount of from about 0.5 to about 5 weight %, based on total imageable layer dry weight.

The imageable layer can also include a variety of optional compounds including but not limited to, dispersing agents, humectants, biocides, plasticizers, surfactants for coatability or other properties, viscosity builders, pH adjusters, drying agents, defoamers, preservatives, antioxidants, development aids, rheology modifiers or combinations thereof, or any other addenda commonly used in the lithographic art, in conventional amounts. Useful viscosity builders include hydroxypropyl cellulose, hydroxyethyl cellulose, carboxymethyl cellulose, and poly(vinyl pyrrolidones).

### Imageable Elements

The imageable elements can be formed by suitable application of a radiation-sensitive composition as described above to a suitable substrate to form an imageable layer. This substrate can be treated or coated in various ways as described below prior to application of the radiation-sensitive composition to improve hydrophilicity. Typically, there is only a single imageable layer comprising the radiation-sensitive composition.

The substrate generally has a hydrophilic surface, or at least a surface that is more hydrophilic than the applied radiation-sensitive composition on the imaging side. The substrate comprises a support that can be composed of any material that is conventionally used to prepare imageable elements such as lithographic printing plates. It is usually in the form of a sheet, film, or foil (or web), and is strong, stable, and flexible and resistant to dimensional change under conditions of use so that color records will register a full-color image. Typically, the support can be any self-supporting material including polymeric films (such as polyester, polyethylene, polycarbonate, cellulose ester polymer, and polystyrene films), glass, ceramics, metal sheets or foils, or stiff papers (including resin-coated and metallized papers), or a lamination of any of these materials (such as a lamination of an aluminum foil onto a polyester film). Metal supports include sheets or foils of aluminum, copper, zinc, titanium, and alloys thereof.

Polymeric film supports may be modified on one or both flat surfaces with a “subbing” layer to enhance hydrophilicity, or paper supports may be similarly coated to enhance planarity. Examples of subbing layer materials include but are not limited to, alkoxysilanes, amino-propyltriethoxysilanes, glycidioxypropyl-triethoxysilanes, and epoxy functional polymers, as well as conventional hydrophilic subbing materials used in silver halide photographic films (such as gelatin and other naturally occurring and synthetic hydrophilic colloids and vinyl polymers including vinylidene chloride copolymers).

One useful substrate is composed of an aluminum support that may be treated using techniques known in the art, including roughening of some type by physical (mechanical) graining, electrochemical graining, or chemical graining, usually followed by acid anodizing. The aluminum support can be roughened by physical or electrochemical graining and then anodized using phosphoric or sulfuric acid and conventional procedures. A useful substrate is an electrochemically grained and sulfuric acid anodized aluminum support that provides a hydrophilic surface for lithographic printing.

An interlayer may be formed by treatment of the aluminum support with, for example, a silicate, dextrine, calcium zirconium fluoride, hexafluorosilicic acid, poly(vinyl phosphonic acid) (PVPA), vinyl phosphonic acid copolymer, poly[(meth)acrylic acid], poly(acrylic acid), or an acrylic acid copolymer to increase hydrophilicity. Still further, the aluminum support may be treated with a phosphate solution that may further contain an inorganic fluoride (PF). The aluminum support can be electrochemically-grained, phosphoric acid-anodized, and treated with poly(acrylic acid) using known procedures to improve surface hydrophilicity.

The thickness of the substrate can be varied but should be sufficient to sustain the wear from printing and thin enough to wrap around a printing form. Useful embodiments include a treated aluminum foil having a thickness of at least 100 μm and up to and including 700 μm.

The backside (non-imaging side) of the substrate may be coated with antistatic agents and/or slipping layers or a matte layer to improve handling and “feel” of the imageable element.

The substrate can also be a cylindrical surface having the radiation-sensitive composition applied thereon, and thus be an integral part of the printing press. The use of such imaging cylinders is described for example in U.S. Pat. No. 5,713,287 (Gelbart).

The radiation-sensitive composition can be applied to the substrate as a solution or dispersion in a coating liquid using any suitable equipment and procedure, such as spin coating, knife coating, gravure coating, die coating, slot coating, bar coating, wire rod coating, roller coating, or extrusion hopper coating. The composition can also be applied by spraying onto a suitable support (such as an on-press printing cylinder). Typically, the radiation-sensitive composition is applied and dried to form an imageable layer and an overcoat formulation is applied to that layer.

Illustrative of such manufacturing methods is mixing the free radically polymerizable composition, non-free radically polymerizable polymeric binders, initiator composition, infrared radiation absorbing compound, and any other components of the radiation-sensitive composition in a suitable organic solvent or mixtures thereof [such as methyl ethyl ketone(2-butanone), methanol, ethanol, 1-methoxy-2-propanol, iso-propyl alcohol, acetone, γ-butyrolactone, n-propanol, tetrahydrofuran, and others readily known in the art, as well as mixtures thereof], applying the resulting solution to a substrate, and removing the solvent(s) by evaporation under suitable drying conditions. Some representative coating solvents and imageable layer formulations are described in the Invention Examples below. After proper drying, the coating weight of the imageable layer is generally at least 0.1 and up to and including 5 g/m² or at least 0.5 and up to and including 3.5 g/m².

Layers can also be present under the imageable layer to enhance developability or to act as a thermal insulating layer. The underlying layer should be soluble or at least dispersible in the developer and typically have a relatively low thermal conductivity coefficient.

The various layers may be applied by conventional extrusion coating methods from melt mixtures of the respective layer compositions. Typically such melt mixtures contain no volatile organic solvents.

Intermediate drying steps may be used between applications of the various layer formulations to remove solvent(s) before coating other formulations. Drying steps at conventional times and temperatures may also help in preventing the mixing of the various layers.

Once the various layers have been applied and dried on the substrate, the imageable element can be enclosed in water-impermeable material that substantially inhibits the transfer of moisture to and from the imageable element as described in U.S. Pat. No. 7,175,969 (noted above) that is incorporated herein by reference.

### Topcoat Layer Formulations

The imageable element optionally includes what is conventionally known as an overcoat or topcoat layer (such as an oxygen impermeable topcoat) applied to and disposed over the imageable layer for example, as described in WO 99/06890 (Pappas et al.). Such topcoat layers comprise one or more water-soluble polymer binders chosen from such polymers as poly(vinyl alcohol)s, poly(vinyl pyrrolidone), poly(ethyleneimine), poly(vinyl imidazole), and copolymers of two or more of vinyl pyrrolidone, ethyleneimine, and vinyl imidazole, and generally have a dry coating weight of at least 0.1 and up to and including 2 g/m² (typically from about 0.1 to about 0.5 g/m²) in which the water-soluble polymer(s) comprise at least 50% and up to 98% of the dry weight of the topcoat layer. Topcoat layer polymer binders are also described in U.S. Pat. No. 3,458,311 (Alles), U.S. Pat. No. 4,072,527 (Fanni), and U.S. Pat. No. 4,072,528 (Bratt), and EP Publications 275,147A2 (Wade et al.), 403,096A2 (Ali), 354,475A2 (Zertani et al.), 465,034A2 (Ueda et al.), and 352,630A2 (Zertani et al.).

The topcoat layer can also include a composition that is capable of changing color upon exposure to imaging infrared radiation. This composition can comprise various component formulations. In one embodiment, it comprises: (1) an infrared absorbing compound, (2) a compound that, in the presence of this IR absorbing compound generates an acid in response to the imaging infrared radiation, and optionally (3) one or more compounds that provide a color change in the presence of an acid. Each of these components is defined below. In some embodiments, components (1) and (3) are the same, while in other embodiments, they are different. In the latter embodiments, component (3) can be a spirolactone or spirolactam colorant precursor. Such compounds are generally colorless or weakly colored until the presence of an acid causes the ring to open providing a colored species, or more intensely colored species.

Examples of useful colorant precursors in the topcoat include but are not limited to, Crystal Violet Lactone, Malachite Green Lactone, 3-(N,N-diethylamino)-6-chloro-7-(β-ethoxyethylamino)fluoran, 3-(N,N,N-triethylamino)-6-methyl-7-anilinofluoran, 3-(N,N-diethylamino)-7-chloro-7-o-chlorofluoran, 2-(N-phenyl-N-methylamino)-6-(N-p-tolyl-N-ethyl)aminofluoran, 2-anilino-3-methyl-6-(N-ethyl-p-toluidino)fluoran, 3,6-dimethoxyfluoran, 3-(N,N-diethylamino)-5-methyl-7-(N,N-dibenzylamino)fluoran, 3-(N-cyclohexyl-N-methylamino)-6-methyl-7-anilinofluoran, 3-(N,N-diethylamino)-6-methyl-7-anilinofluoran, 3-(N,N-diethylamino)-6-methyl-7-xylidinofluoran, 3-(N,N-diethylamino)-6-methyl-7-chlorofluoran, 3-(N,N-diethylamino)-6-methoxy-7-chlorofluoran, 3-(N,N-diethylamino)-7-(4-chloroanilino)fluoran, 3-(N,N-diethylamio)-7-chlorofluoran, 3-(N,N-diethylamino)-7-benzylaminofluoran, 3-(N,N-diethylamino)-7,8-benzofluoran, 3-(N,N-dibutylamino)-6-methyl-7-anilinofluoran, 3-(N,N-dibutylamino)-6-methyl-7-xylidinofluoran, 3-piperidino-6-methyl-7-anilinofluoran, 3-pyrrolidino-6-methyl-7-anilinofluoran, 3,3-bis(1-ethyl-2-methylindol-3-yl)phthalide, 3,3-bis((1-n-butyl-2-methylindol-3-yl)phthalide, 3,3-bis(p-dimethylaminophenyl)-6-dimethylaminophthalide, 3-(4-diethylamino-2-ethoxyphenyl)-3-(1-ethyl-2-methylindol-3-yl)-4-azaphthalide, and 3-(4-diethylaminophenyl)-3-(1-ethyl-2-methylindol-3-yl)phthalide.

The colorant precursors can be present in the topcoat layer in an amount of at least 1 and up to 12%, and typically from about 3 to about 8%, based on the dry topcoat layer weight.

### Imaging Conditions

During use, the imageable element is exposed to a suitable source of imaging or exposing near-infrared or infrared radiation, depending upon the radiation absorbing compound present in the radiation-sensitive composition, at a wavelength of from about 700 to about 1500 nm. For example, imaging can be carried out using imaging or exposing radiation, such as from an infrared laser at a wavelength of at least 700 nm and up to and including about 1400 nm and typically at least 750 nm and up to and including 1200 nm. Imaging can be carried out using imaging radiation at multiple wavelengths at the same time if desired.

The laser used to expose the imageable element is usually a diode laser, because of the reliability and low maintenance of diode laser systems, but other lasers such as gas or solid-state lasers may also be used. The combination of power, intensity and exposure time for laser imaging would be readily apparent to one skilled in the art. Presently, high performance lasers or laser diodes used in commercially available imagesetters emit infrared radiation at a wavelength of at least 800 nm and up to and including 850 nm or at least 1060 and up to and including 1120 nm.

The imaging apparatus can function solely as a platesetter or it can be incorporated directly into a lithographic printing press. In the latter case, printing may commence immediately after imaging and development, thereby reducing press set-up time considerably. The imaging apparatus can be configured as a flatbed recorder or as a drum recorder, with the imageable member mounted to the interior or exterior cylindrical surface of the drum. An example of an useful imaging apparatus is available as models of Creo Trendsetter® platesetters available from Eastman Kodak Company (Burnaby, British Columbia, Canada) that contain laser diodes that emit near infrared radiation at a wavelength of about 830 nm. Other suitable imaging sources include the Crescent 42T Platesetter that operates at a wavelength of 1064 nm (available from Gerber Scientific, Chicago, Ill.) and the Screen PlateRite 4300 series or 8600 series platesetter (available from Screen, Chicago, Ill.). Additional useful sources of radiation include direct imaging presses that can be used to image an element while it is attached to the printing plate cylinder. An example of a suitable direct imaging printing press includes the Heidelberg SM74-DI press (available from Heidelberg, Dayton, Ohio).

Imaging with infrared radiation can be carried out generally at imaging energies of at least 20 mJ/cm² and up to and including 500 mJ/cm², and typically at least 50 and up to and including 300 mJ/cm² depending upon the sensitivity of the imageable layer.

For example, in some embodiments, the imageable element contains an IR-sensitive dye and the imagewise exposing step A is carried out using radiation having a maximum wavelength of from about 700 to about 1200 nm at an energy level of from about 20 to about 500 mJ/cm².

While laser imaging is desired in the practice of this invention, imaging can be provided by any other means that provides thermal energy in an imagewise fashion. For example, imaging can be accomplished using a thermoresistive head (thermal printing head) in what is known as “thermal printing”, described for example in U.S. Pat. No. 5,488,025 (Martin et al.). Thermal print heads are commercially available (for example, a Fujitsu Thermal Head FTP-040 MCS001 and TDK Thermal Head F415 HH7-1089).

### Development and Printing

With or without a post-exposure baking step after imaging and before development, the imaged elements can be developed “on-press” as described in more detail below. In most embodiments, a post-exposure baking step is omitted. On-press development avoids the use of alkaline developing solutions typically used in conventional processing apparatus. The imaged element is mounted on press wherein the unexposed regions in the imageable layer are removed by a suitable fountain solution, lithographic printing ink, or a combination of both, when the initial printed impressions are made. Typical ingredients of aqueous fountain solutions include pH buffers, desensitizing agents, surfactants and wetting agents, humectants, low boiling solvents, biocides, antifoaming agents, and sequestering agents. A representative example of a fountain solution is Varn Litho Etch 142W+Varn PAR (alcohol sub) (available from Varn International, Addison, Ill.).

The fountain solution is taken up by the non-imaged regions, that is, the surface of the hydrophilic substrate revealed by the imaging and development steps, and ink is taken up by the imaged (non-removed) regions of the imaged layer. The ink is then transferred to a suitable receiving material (such as cloth, paper, metal, glass, or plastic) to provide a desired impression of the image thereon. If desired, an intermediate “blanket” roller can be used to transfer the ink from the imaged member to the receiving material. The imaged members can be cleaned between impressions, if desired, using conventional cleaning means.

The following examples are provided to illustrate the practice of the invention but are by no means intended to limit the invention in any manner.

### EXAMPLES

The following components were used in the Examples described below:

Blue 63 is a 3-(4-diethylamino-2-ethoxyphenyl)-3-(1-ethyl-2-methylindol-3-yl)-4-azaphthalide from Yamamoto Chemicals, Inc.

Byk® 336 is available from Byk Chemie (Wallingford, Conn.) in a 25 wt. % xylene/methoxypropyl acetate solution.

Graft polymer A is a polymer dispersion containing 20 wt% styrene, 70 wt. % acrylonitrile, and 10 wt. % polyethylene glycol methyl ether methacrylate; 24% in propanol/water (76/24).

Initiator A is bis(4-t-butylphenyl) iodonium tetraphenylborate.

IR Dye A is a cyanine dye with the following structure:

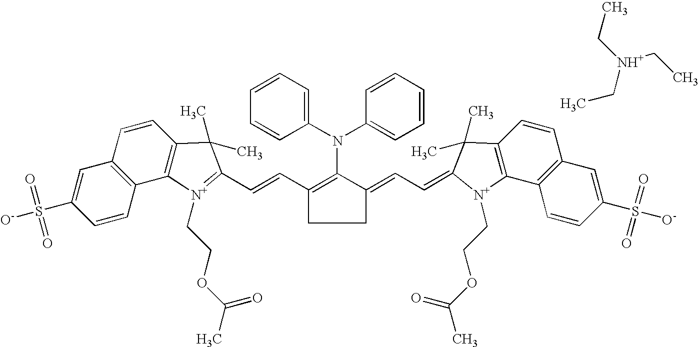

Irgacure® 250 is a 75 wt. % solution of iodonium, (4-methylphenyl)[4-(2-methylpropyl)phenyl]-, hexafluorophosphate in propylene carbonate that was obtained from Ciba Specialty Chemicals (Tarrytown, N.Y.).

LL02 is a poly(vinyl acetate) with a hydrolysis degree of 45.0-51.0 mol %, commercially available from Nippon Gohsei.

MEK represents methyl ethyl ketone.

Oligomer A is a urethane acrylate prepared by reacting DESMODUR N100 (an aliphatic polyisocyanate resin based on hexamethylene diisocyanate from Bayer Corp., Milford, Conn.) with hydroxyethyl acrylate and pentaerythritol triacrylate (80 wt. % solution in 2-butanone). It contains 0.76 equivalent mol of C═C group per 100 g sample.

PGME represents 1-methoxy-2-propanol.

PEGDA is a poly(ethylene glycol) diacid (MW=600) from Aldrich Chemical Co (Milwaukee, Wis.).

Sipomer PAM-100 is an ethylene glycol methacrylate phosphate with 4-5 ethylene glycol units that was obtained from Rhodia.

Sartomer SR-399 is dipentaerythritol pentaacrylate that was obtained from Sartomer Company, Inc. (Exton, Pa.). It contains 0.67 equivalent mol of C═C group per 100 g sample.

Sartomer SR-494 is ethoxylated pentaerythritol tetraacrylate from Sartomer Company, Inc. It contains 0.76 equivalent mol of ethoxylate group per 100 g sample.

### Invention Example 1

The coating composition A shown below in TABLE I was prepared to give a 5.6% w/w solution in a solvent mixture of 40% n-propanol, 25% PGME, 30% MEK, and 5% water. The resulting solution was applied to an electrochemically grained, sulfuric acid-anodized, aluminum-containing substrate that had been treated with a poly(vinyl phosphonic acid) (PVPA) using a slot coater at 2.5 cm³/ft² (26.9 cm³/m²) and dried to give a dry imageable layer coverage of about 1.2 g/m². The coating drum temperature was 210° F. (98.9° C.) and the duration was 80 seconds. After cooling to room temperature, a negative-working imageable element (printing plate precursor) was obtained.

Samples of the imageable element were treated under various conditions in order to accelerate the effects of ageing. In one test, elements were wrapped in interleaving and foil and then treated for 5 days at 48° C. (dry aging test). In another test, elements were hung in a humidity chamber for 5 days at 38° C. and 80% relative humidity (humidity aging test). In a third test, elements were placed at room temperature in the dark (inside a cardboard box) for 5-10 days (natural aging test).

After the various aging tests (natural, dry and humidity aging), all aged element samples were exposed from 50 to 125 mJ/cm² on a Kodak® Trendsetter 3244x imagesetter. The imaged elements were then directly mounted on an ABDick duplicator press charged with Van Son rubber-based black ink. The fountain solution was Vam 142W etch at 3 oz per gallon (23.4 ml/liter) and PAR alcohol replacement at 3 oz per gallon (23.4 ml/liter). The printing press was run for 200 impressions and the development of the printing plates was assessed from the 200th sheets by visual evaluating imaging quality (see TABLE II below for development results).

In a press run length test, a sample of the imageable element was subsequently exposed at 150 mJ/cm² at 15 watts on a Kodak® Trendsetter 3244x image setter, and was used to provide about 40,000 good impressions on a Komori press with a wear ink containing 1.5% calcium carbonate.

### Comparative Example 1

The coating composition B shown below in TABLE I was prepared to give a 5.6% w/w solution in a solvent mixture of 40% n-propanol, 25% PGME, 30% MEK, and 5% water. The resulting solution was applied to an electrochemically grained, sulfuric acid-anodized, aluminum-containing substrate that had been treated with a poly(vinyl phosphonic acid) (PVPA) using a slot coater at 2.5 cm³/ft² (26.9 cm³/m²) and dried to give a dry imageable layer coverage of about 1.2 g/m². The coating drum temperature was 210° F. (98.9° C.) and the duration was 80 seconds. After cooling to room temperature, a negative-working imageable element (printing plate precursor) was obtained.

Samples of the imageable element were tested using the three aging tests described above for Invention Example 1.

After the three aging tests (natural, dry and humidity aging), the samples were exposed from 50 to 125 mJ/cm² using a Kodak® Trendsetter 3244x image setter and then directly mounted on an ABDick duplicator press charged with Van Son rubber-based black ink. The fountain solution was Varn 142W etch at 3 oz per gallon (23.4 ml/liter) and PAR alcohol replacement at 3 oz per gallon (23.4 ml/liter) and the press was run for 200 impressions. The development of the printing plates was assessed from the 200th sheets by visual evaluating imaging quality (see TABLE II below for development results).

In a press run length test, a sample of the imageable element was subsequently exposed at 150 mJ/cm² at 15 watts using a Kodak® Trendsetter 3244x image setter and was used to provide only 20,000 good impressions on a Komori press using a wear ink containing 1.5% calcium carbonate.

### Comparative Example 2

The coating composition C shown in TABLE I below was prepared to give a 5.6% w/w solution in a solvent mixture of 40% n-propanol, 25% PGME, 30% MEK, and 5% water. The resulting solution was applied to an electrochemically grained, sulfuric acid-anodized, aluminum-containing substrate that had been treated with a poly(vinyl phosphonic acid) (PVPA) using a slot coater at 2.5 cm³/ft² (26.9 cm³/m²) and dried to give a dry imageable layer coverage of about 1.2 g/m². The coating drum temperature was 210° F. (98.9° C.) and the duration was 80 seconds. After cooling to room temperature, a negative-working imageable element (printing plate precursor) was obtained.

Samples of the imageable element were tested using the three aging tests described in Invention Example 1.

After the various aging tests (natural, dry and humidity aging), all samples were exposed from 50 to 125 mJ/cm² using a Kodak® Trendsetter 3244x image setter and were then directly mounted on an ABDick duplicator press charged with Van Son rubber-based black ink and evaluated as described in Invention Example 1. The development of the plates was assessed from the 200th sheets by visual evaluating imaging quality (see TABLE II below for development results), and the aged plates showed background sensitivity.

In a press run length test, a sample of the imageable element was subsequently exposed at 150 mJ/cm² at 15 watts using a Kodak® Trendsetter 3244x image setter and was used to provide about 45,000 good impressions on a Komori press with a wear ink containing 1.5% calcium carbonate.

### Invention Example 2

The coating composition D shown in TABLE I below was prepared to give a 5.6% w/w solution in a solvent mixture of 40% n-propanol, 25% PGME, 30% MEK, and 5% water. The resulting solution was applied to an electrochemically grained, sulfuric acid-anodized, aluminum-containing substrate that had been treated with a poly(vinyl phosphonic acid) (PVPA) using a slot coater at 2.5 cm³/ft² (26.9 cm³/m²) and dried to give a dry imageable layer coverage of about 1.2 g/m². The coating drum temperature was 210° F. (98.9° C.) and the duration was 80 seconds. After cooling to room temperature, a negative-working imageable element (printing plate precursor) was obtained.

Samples of the imageable element were tested using the three aging tests described above in Invention Example 1.

After the aging tests (natural, dry and humidity aging), the samples were exposed from 50 to 125 mJ/cm² using a Kodak® Trendsetter 3244x image setter. The imaged elements were then directly mounted on an ABDick duplicator press charged with Van Son rubber-based black ink as described above for Invention Example 1 and the press was run for 200 impressions. The development of the plates was assessed from the 200th sheets by visual evaluating imaging quality (see TABLE II below for development results).

In a press run length test, a sample of the imageable element was subsequently exposed at 150 mJ/cm² at 15 watts using a Kodak® Trendsetter 3244x image setter and was used to provide about 40,000 good impressions on a Komori press with a wear ink containing 1.5% calcium carbonate.

### Invention Example 3

The coating composition E shown below in TABLE I was prepared to give a 5.6% w/w solution in a solvent mixture of 40% n-propanol, 25% PGME, 30% MEK, and 5% water. The resulting solution was applied to an electrochemically grained, sulfuric acid-anodized, aluminum-containing substrate that had been treated with a poly(vinyl phosphonic acid) (PVPA) using a slot coater at 2.5 cm³/ft² (26.9 cm³/m²) and dried to give a dry imageable layer coverage of about 1.2 g/m². The coating drum temperature was 210° F. (98.9° C.) and the duration was 80 seconds. After cooling to room temperature, a negative-working imageable element (printing plate precursor) was obtained.

Samples of the imaged element were tested using the three aging tests described above in Invention Example 1.

After the various aging tests (natural, dry and humidity aging), all samples were exposed from 50 to 125 mJ/cm² using a Kodak® Trendsetter 3244x image setter and then directly mounted on an ABDick duplicator press charged with Van Son rubber-based black ink as described above for Invention Example 1. The printing press was run for 200 impressions and the development of the printing plates was assessed from the 200th sheets by visual evaluating imaging quality (see TABLE II below for development results).

In a press run length test, a sample of the imageable element was subsequently exposed at 150 mJ/cm² at 15 watts using a Kodak® Trendsetter 3244x image setter and was used to provide about 35,000 good impressions on a Komori press with a wear ink containing 1.5% calcium carbonate.

TABLE I

| | % of components in solid (by weight) | | | | |
|---|---|---|---|---|---|
| | Com- | Com- | Com- | | |
| | posi- | posi- | posi- | Composi- | Composi- |
| Components | tion A | tion B | tion C | tion D | tion E |
| Sartomer SR494 | 13.0 | 26.0 | 0.0 | 9.0 | 18.0 |
| Oligomer A | 13.0 | 0.0 | 26.0 | 17.0 | 8.0 |
| Graft polymer A | 38.0 | 38.0 | 38.0 | 38.0 | 38.0 |
| Initiator A | 5.0 | 5.0 | 5.0 | 5.0 | 5.0 |
| Irgacure ® 250 | 2.7 | 2.7 | 2.7 | 2.7 | 2.7 |
| IR Dye A | 3.6 | 3.6 | 3.6 | 3.6 | 3.6 |
| Byk ® 336 | 2.1 | 2.1 | 2.1 | 2.1 | 2.1 |
| Sipomer PAM-100 | 1.4 | 1.4 | 1.4 | 1.4 | 1.4 |
| Blue-63 | 3.7 | 3.7 | 3.7 | 3.7 | 3.7 |
| LL02 | 12.0 | 12.0 | 12.0 | 12.0 | 12.0 |
| PEGDA | 5.5 | 5.5 | 5.5 | 5.5 | 5.5 |
| MR* | 1.77 | 1.00 | n/a | 2.46 | 1.34 |

*MR is a mole ratio of terminal acrylate groups to the alkylene glycol units in the free radically polymerizable composition

TABLE II

| | Development Assessment | | |
|---|---|---|---|
| Printing Plate Source | Natural aging | Dry aging | Humidity aging |
| Invention Example 1 | 1 | 1 | 1 |
| Invention Example 2 | 1 | 1 | 1 |
| Invention Example 3 | 1 | 1 | 1 |
| Comparative Example 1 | 1 | 1 | 1 |
| Comparative Example 2 | 1 | 2 | 3 |

1: clear differentiation between exposed and non-exposed areas, clean background.
2: clear differentiation between exposed and non-exposed areas, not complete clean in background.
3: no differentiation between exposed and non-exposed areas, both having ink heavily.

These results show that a certain mole ratio (MR) of terminal acrylate groups to the alklyene glycol units in the free radically polymerizable composition is required in order to achieve long press run length and good development. Without the presence of the alklyene glycol units (Comparative Example 2), the imaged elements were poorly developed after aging. When a high content of alkylene glycol units was present (MR=1.00 as in Comparative Example 1), the resulting printing plates exhibited shorter press run length.

The invention has been described in detail with particular reference to certain preferred embodiments thereof, but it will be understood that variations and modifications can be effected within the spirit and scope of the invention.

1. A negative-working, on-press developable imageable element comprising a substrate having thereon an imageable layer as the outermost layer, said imageable layer comprising:
a non-polymeric free radically polymerizable composition,
an initiator composition capable of generating radicals sufficient to initiate polymerization of said free radically polymerizable composition upon exposure to imaging infrared radiation,
an infrared radiation absorbing compound, and
one or more non-free radically reactive polymeric binders,
wherein said free radically polymerizable composition comprises two or more ethylenically unsaturated compounds, each of which has two or more terminal acrylate groups, provided at least one of said ethylenically unsaturated compounds further comprises alkylene glycol units, and
further provided that the molar ratio of terminal acrylate groups to the alkylene glycol units in said non-polymeric free radically polymerizable composition is from about 1.25:1 to about 3:1.

2. The imageable element of claim 1 wherein the molar ratio of terminal acrylate groups to the alkylene glycol units in said non-polymeric free radically polymerizable composition is from about 1.25:1 to about 2.5:1.

3. The imageable element of claim 1 wherein said ethylenically unsaturated compounds containing said alkylene glycol units are represented by the following Structure (Ia):
H₂C═C(R₁)—C(═O)—X—[—CH(R′)—CH(R′)—O—]ₙ— (Ia)
wherein R₁ is hydrogen or methyl, R′ and R″ are independently hydrogen or an alkyl group having 1 to 4 carbon atoms, X is oxy, —NH—, thio, seleno, or an aliphatic group, and n is an integer of from 1 to 50.

4. The imageable element of claim 3 wherein X is oxy or —NH— and n is from 1 to 10.

5. The imageable element of claim 1 wherein said ethylenically unsaturated compounds independently have a molecular weight of less than 5,000.

6. The imageable element of claim 1 wherein said free radically polymerizable composition comprises at least one ethylenically unsaturated compound that has two or more terminal acrylate groups and further comprises alkylene glycol units.

7. The imageable element of claim 1 wherein said free radically polymerizable composition comprises at least one ethylenically unsaturated compound that has two or more terminal acrylate groups and contains no alkylene glycol units.

8. The imageable element of claim 1 wherein at least one of said non-free radical reactive polymeric binders is present as discrete particles.

9. The imageable element of claim 1 comprising a primary non-free radically reactive polymeric binder that is optionally present as discrete particles, and
a secondary non-free radically reactive polymeric binder comprising a poly(vinyl acetate) that has a degree of hydrolysis of less than 60 mol %.

10. The imageable element of claim 9 wherein said primary non-free radically polymerizable polymeric binder is present in an amount of at least 5 and up to 70 weight %, said secondary non-free radically polymerizable polymeric binder is present in an amount of at least 1 and up to 40 weight %, both based on total dry imageable layer weight, and wherein the weight ratio of said secondary non-free radically polymerizable polymeric binder to said first non-free radically polymerizable polymeric binder is from about 1:1 to about 1:20.

11. The imageable element of claim 1 wherein said substrate is a sulfuric acid-anodized aluminum-containing substrate.

12. The imageable element of claim 1 wherein said infrared radiation absorbing compound is an infrared radiation absorbing dye that is present in an amount of from about 1 to about 30 weight % based on total imageable layer weight.

13. The imageable element of claim 1 wherein said initiator composition comprises an onium salt.

14. The imageable element of claim 13 wherein said onium salt is an iodonium borate comprising a diaryliodonium borate compound represented by the following Structure (II): 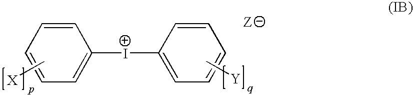
wherein X and Y are independently halo, alkyl, alkyloxy, or cycloalkyl groups or two or more adjacent X or Y groups can be combined to form a fused ring with the respective phenyl rings, p and q are independently 0 or integers of 1 to 5, and
Z⁻ is an organic anion represented by the following Structure (III): 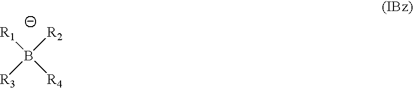
wherein R₁, R₂, R₃, and R₄ are independently alkyl, aryl, alkenyl, alkynyl, cycloalkyl, or heterocyclyl groups, or two or more of R₁, R₂, R₃, and R₄ can be joined together to form a heterocyclic ring with the boron atom.

15. A method of making an imaged element comprising:
A) imagewise exposing the negative-working imageable element of claim 1 to form exposed and non-exposed regions,
B) with or without a preheat step, developing said imagewise exposed element on-press using a fountain solution, lithographic printing ink, or both, to remove predominantly only said non-exposed regions.

16. The method of claim 15 wherein said imageable element contains an IR-sensitive dye and said imagewise exposing step A is carried out using radiation having a maximum wavelength of from about 700 to about 1200 nm at an energy level of from about 20 to about 500 mJ/cm², and wherein said imageable element comprises a sulfuric acid-anodized aluminum-containing substrate.

17. The method of claim 15 wherein said imageable element comprises ethylenically unsaturated compounds containing alkylene glycol units that are represented by the following Structure (Ia):
H₂C═C(R₁)—C(═O)—X—[—CH(R′)—CH(R″)—O—]ₙ— (Ia)
wherein R₁ is hydrogen or methyl, R′ and R″ are independently hydrogen or an alkyl group having 1 to 4 carbon atoms, X is oxy, —NH—, thio, seleno, or an aliphatic group, and n is an integer of from 1 to 50.

18. The method of claim 17 wherein the molar ratio of said terminal acrylate groups to said alkylene glycol units in said non-polymeric free radically polymerizable composition of said imageable element is from about 1.25:1 to about 2.5:1.

19. The method of claim 17 wherein said ethylenically unsaturated compounds independently have a molecular weight of less than 5,000, and at least one of said non-free radically polymerizable polymeric binders is present as discrete particles.

20. An imaged lithographic printing plate obtained from the method of claim 15.
